(19) United States
(12) Patent Application Publication
(10) Pub. No.: US 2021/0327745 A1
(43) Pub. Date: Oct. 21, 2021

(54) PICKUP AND CONTACT DEVICE

(71) Applicant: Powertech Technology Inc., Hsinchu County (TW)

(72) Inventors: Yi Chi Wang, Hsinchu County (TW); Yu Kai Chuang, Hsinchu County (TW)

(73) Assignee: Powertech Technology Inc., Hsinchu County (TW)

(21) Appl. No.: 16/921,962

(22) Filed: Jul. 7, 2020

(30) Foreign Application Priority Data
Apr. 16, 2020 (TW) 109112768

(51) Int. Cl. H01L 21/683; H01L 21/66; H01L 21/67

(52) U.S. Cl. CPC H01L 21/6838; H01L 21/67103; H01L 22/30

(57) ABSTRACT

A pickup and contact device is adapted to be connected to a moving device to move a picked-up electronic element to an electrical testing zone. The moving device pressurizes the electronic element through the pickup and contact device, so that a contact point of the electronic element stably contacts a contact pad of the electrical testing zone. The pickup and contact device includes a main body including a base and a contact portion and a plurality of heat dissipation fins disposed at two opposite sides of the base. The contact portion is adapted to pick up the electronic element and to move the electronic element to the electrical testing zone along with the moving device. When the electronic element is tested in the electrical testing zone, heat emitted from the electronic element is adapted to be transmitted out through the heat dissipation fins of the main body.

### CROSS-REFERENCE TO RELATED APPLICATION

This application claims the priority benefit of Taiwan patent application serial no. 109112768, filed on Apr. 16, 2020. The entirety of the above-mentioned patent application is hereby incorporated by reference herein and made a part of this specification.

### BACKGROUND

### Technical Field

The disclosure relates to a pickup and contact device, and more particularly, to a pickup and contact device capable of facilitating heat dissipation.

### Description of Related Art

Generally, in the manufacturing process of a wafer, yield is required to be tested. Along with technology advancement, the power of chips advances. Chips of this type may require a specific testing environment (e.g., a low-temperature or a high-pressure environment), so as to prevent overheating from occurring during a testing process. Nevertheless, costs of test stations for building such specific testing environment are considerably high, so how a favorable heat dissipation effect may be conveniently provided in a chip testing process is an important goal in this field.

### SUMMARY

The disclosure provides a pickup and contact device capable of facilitating heat dissipation.

The disclosure provides a pickup and contact device adapted to be connected to a moving device to move a picked-up electronic element to an electrical testing zone. The moving device pressurizes the electronic element through the pickup and contact device, so that a contact point of the electronic element stably contacts a contact pad of the electrical testing zone. The pickup and contact device includes a main body including a base and a contact portion and a plurality of heat dissipation fins disposed at the opposite side of the contact portion of the base. The contact portion is adapted to pick up the electronic element and to move the electronic element to the electrical testing zone along with the moving device. When the electronic element is tested in the electrical testing zone, heat emitted from the electronic element is adapted to be transmitted out through the heat dissipation fins of the main body.

In an embodiment of the disclosure, the main body further includes a plurality of fixing convex columns located among the heat dissipation fins. The fixing convex columns have a plurality of first fixing holes, and the fixing convex columns are flushed with the heat dissipation fins.

In an embodiment of the disclosure, the heat dissipation fins stand on the base and surround a clearance zone located in a center, and the heat dissipation fins are evenly distributed on a portion outside the clearance zone.

In an embodiment of the disclosure, the pickup and contact device further includes a pipeline penetrating through the main body and extending to the contact portion. The pipeline is adapted to apply a negative pressure inside to suck the electronic element.

In an embodiment of the disclosure, the pickup and contact device further includes a connection member detachably disposed at one side of the main body near the heat dissipation fins. The connection member is adapted to be connected to the moving device together with the main body.

In an embodiment of the disclosure, the heat dissipation fins stand on the base and surround a clearance zone located in a center, and the connection member covers the clearance zone.

In an embodiment of the disclosure, the main body includes a plurality of first fixing holes, and the connection member includes a plurality of second fixing holes corresponding to the first fixing holes. The pickup and contact device further includes a plurality of locking members, and each of the locking members is adapted to penetrate through one of the corresponding first fixing hole and the second fixing hole and to be locked to the other one of the corresponding first fixing hole and the second fixing hole.

In an embodiment of the disclosure, the connection member includes a clip adapted to clip to the moving device.

In an embodiment of the disclosure, the pickup and contact device further includes a fan dispose next to the heat dissipation fins.

In an embodiment of the disclosure, a material of the main body includes metal, graphite, or highly heat-conductive plastic.

To sum up, the pickup and contact device provided by the disclosure is provided with the heat dissipation fins. When the electronic element is tested in the electrical testing zone, heat emitted by the electronic element is adapted to be transmitted out through the heat dissipation fins on the main body, and the temperature of the electronic element is thereby lowered. In this way, even if the electronic element is tested in a normal-temperature and normal-pressure testing environment, the pickup and contact device exhibiting a favorable heat dissipation property may also be used to prevent the electronic element from malfunctioning caused by overheating in the testing process.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a partial schematic view of a pickup and contact device connected to a moving device according to an embodiment of the disclosure.

FIG. 2 is a schematic three-dimensional top view of the pickup and contact device of FIG. 1.

FIG. 3 is a schematic three-dimensional bottom view of the pickup and contact device of FIG. 1.

FIG. 4 is a schematic view of a connection member of the pickup and contact device of FIG. 1.

FIG. 5 is a schematic view of a main body of the pickup and contact device of FIG. 1.

FIG. 6 is a schematic cross-sectional view of the pickup and contact device of FIG. 1 picking up an electronic element to an electrical testing zone.

### DESCRIPTION OF THE EMBODIMENTS

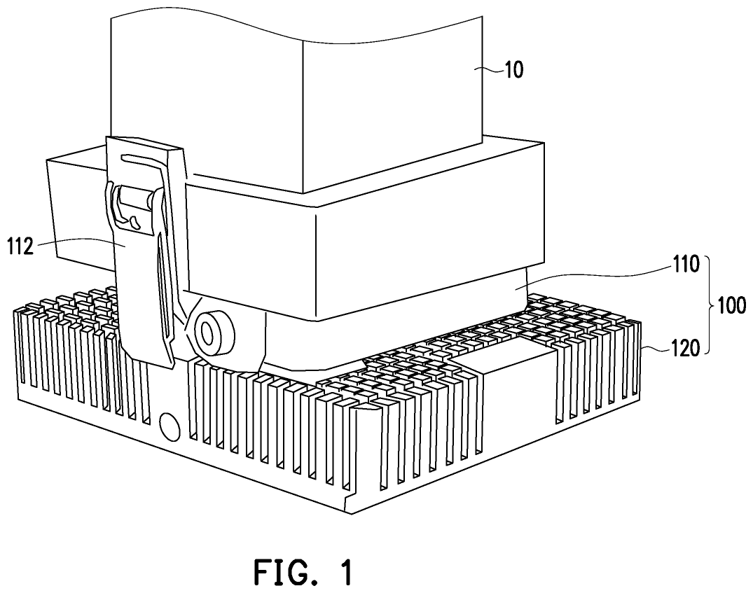

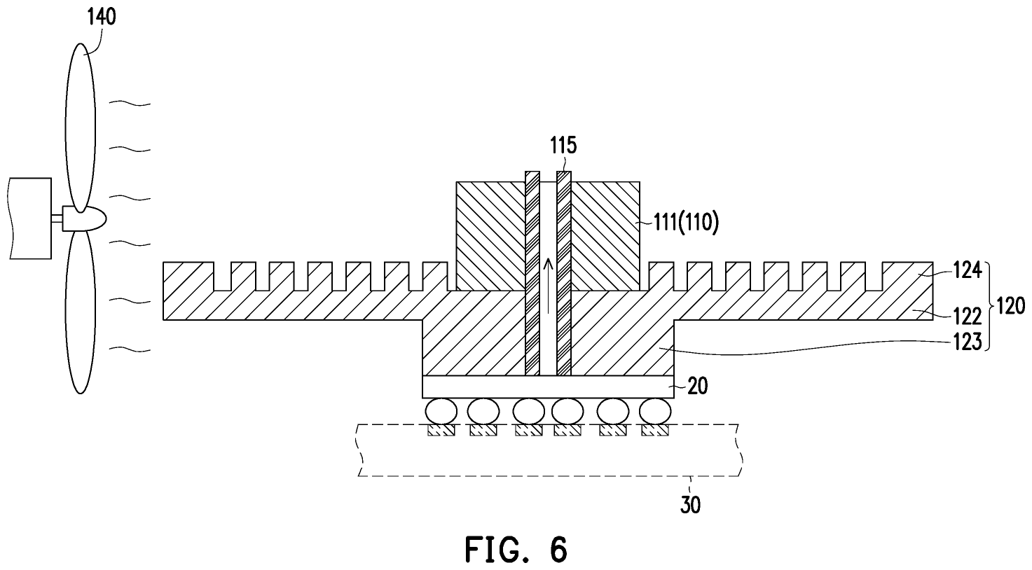

FIG. 1 is a partial schematic view of a pickup and contact device connected to a moving device according to an embodiment of the disclosure. With reference to FIG. 1, a pickup and contact device 100 provided by this embodiment is adapted to be connected to a moving device 10, so as to move a picked-up electronic element 20 (FIG. 6) to an electrical testing zone 30 (FIG. 6). Moreover, the moving device 10 may evenly pressurize the electronic element 20 through the pickup and contact device 100, so as to ensure that a contact point or a solder ball on the electronic element 20 may contact a contact pad on the electrical testing zone 30 to be in conduction with the contact pad. In the present embodiment, the moving device 10 is, for example, a mechanical arm capable of performing one-dimensional, two-dimensional, or three-dimensional movement, but types and movement manners of the moving device 10 are not limited thereto. Besides, in the present embodiment, the electronic element 20 is, for example, a chip or a wafer, but in other embodiments, the electronic element 20 may be a passive element such as a capacitor, an inductor, a resistor, etc., which is not limited thereto.

In the present embodiment, the pickup and contact device 100 is configured to pick up or put down the electronic element 20, and the moving device 10 is configured to bring the electronic element 20 together with the pickup and contact device 100 to or away from the electrical testing zone 30. More specifically, when the electronic element 20 is required to be tested in the electrical testing zone 30, the pickup and contact device 100 picks up the electronic element 20 from a carrier (not shown), and the moving device 10 brings the electronic element 20 together with the pickup and contact device 100 to the electrical testing zone 30. In the testing process, the pickup and contact device 100 is still in contact with (such as still performs vacuum suction on or still clamps) the electronic element 20. Until the end of the testing, the moving device 10 brings the electronic element 20 together with the pickup and contact device 100 away from the electrical testing zone 30 and moves the electronic element 20 together with the pickup and contact device 100 to the corresponding carrier (e.g., a carrier for carrying good or bad products). Finally, the pickup and contact device 100 puts down the electronic element 20 to the carrier.

In this embodiment, when the electronic element 20 is tested, the pickup and contact device 100 is still in contact with the electronic element 20. A special structure is thereby specifically designed on the pickup and contact device 100 in the disclosure for performing heat dissipation on the electronic element 20 during the testing process of the electronic element 20, so as to avoid test failure caused by overheating. Description thereof is provided as follows.

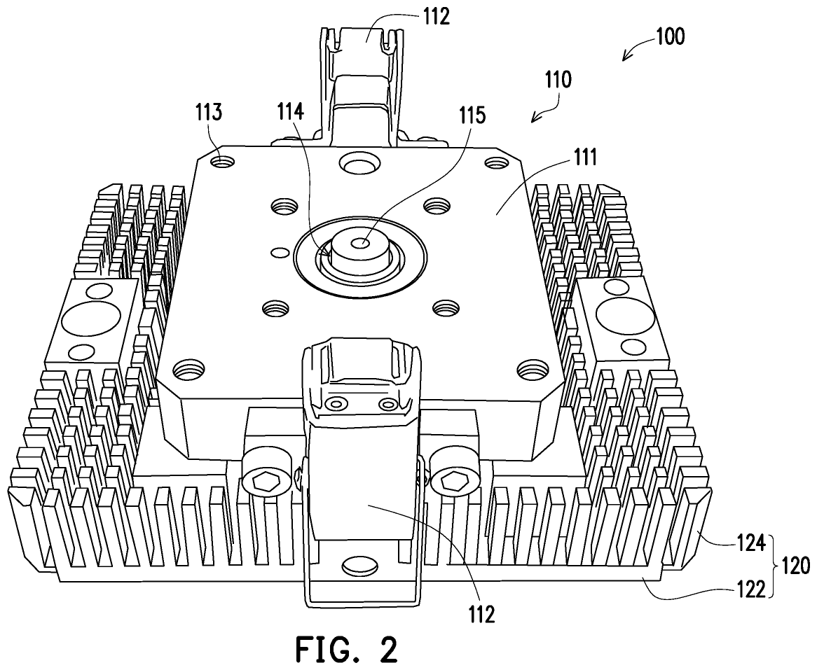

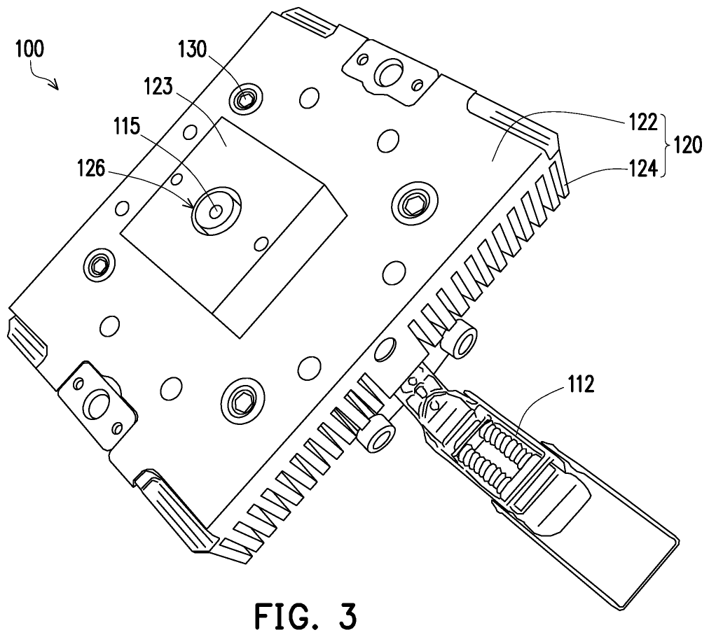

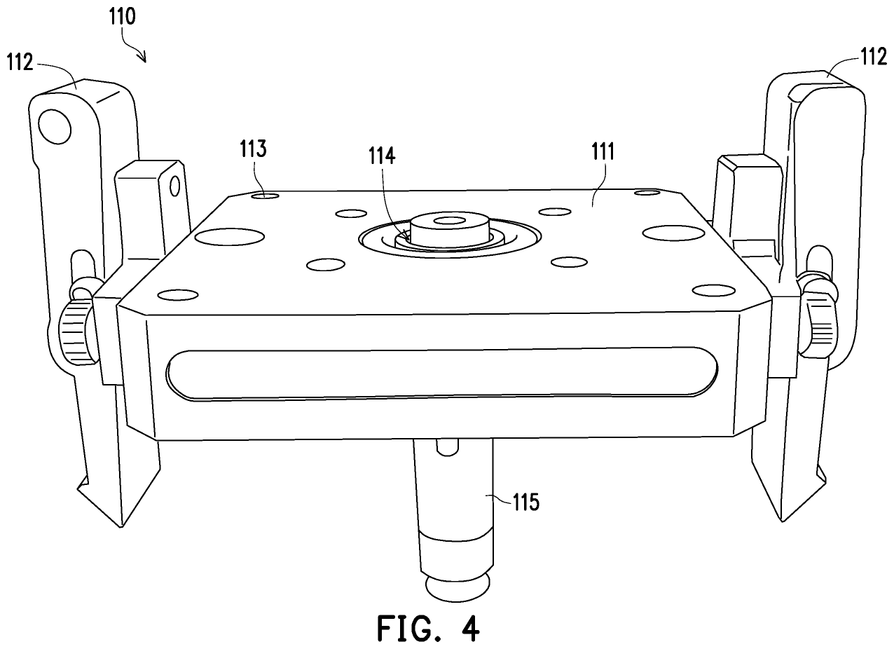

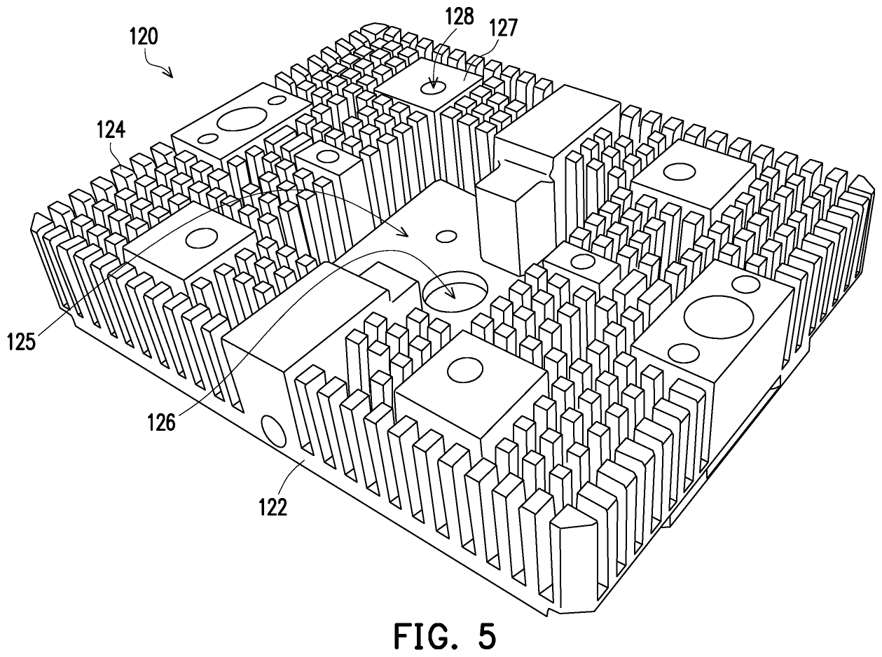

FIG. 2 is a schematic three-dimensional top view of the pickup and contact device of FIG. 1. FIG. 3 is a schematic three-dimensional bottom view of the pickup and contact device of FIG. 1. FIG. 4 is a schematic view of a connection member of the pickup and contact device of FIG. 1. FIG. 5 is a schematic view of a main body of the pickup and contact device of FIG. 1. FIG. 6 is a schematic cross-sectional view of the pickup and contact device of FIG. 1 picking up an electronic element to an electrical testing zone.

With reference to FIG. 2 to FIG. 6, in the present embodiment, the pickup and contact device 100 includes a main body 120 and a connection member 110. The main body 120 is configured to pick up the electronic element 20, and the connection member 110 is detachably disposed on the main body 120 and is adapted to be connected to the moving device 10, so that the main body 120 may move with the moving device 10 together. In the present embodiment, the connection member 110 includes a connection member body 111 and a clip 112 disposed on the connection member body 111, and the clip 112 is configured to clip to the moving device 10. Certainly, in other embodiments, the manner used by the connection member 110 to be fixed to the moving device 10 is not limited thereto. Certainly, in other embodiments, the connection member 110 and the main body 120 may be integrally formed. That is, a structure connected to the moving device 10 is disposed on the main body 120.

As shown in FIG. 3 and FIG. 5, in the present embodiment, the main body 120 includes a base 122 and a contact portion 123 and a plurality of heat dissipation fins 124 disposed at the opposite side of the contact portion 123 of the base 122. The contact portion 123 is adapted to pick up the electronic element 20. As shown in FIG. 3 to FIG. 6, in the present embodiment, the pickup and contact device 100 further includes a pipeline 115 penetrating through the main body 120 and extending to the contact portion 123. Specifically, the pipeline 115 penetrates through a second through hole 114 of the connection member 110 and a first through hole 126 of the main body 120 and is exposed from the contact portion 123 of the main body 120. The pipeline 115 is adapted to suck the electronic element 20 by applying a negative pressure inside, and in this way, the electronic element 20 is in contact with the contact portion 123 of the main body 120.

Certainly, in other embodiments, the main body 120 of the pickup and contact device 100 may also be equipped with a clamping device to pick up the electronic element 20 through clamping. Alternatively, the main body 120 of the pickup and contact device 100 may stick the electronic element 20 up through an adhesion manner. The manner used by the pickup and contact device 100 to pick up the electronic element 20 is not limited to the above.

Note that in the present embodiment, a material of the main body 120 includes metal, graphite, or highly heat-conductive plastic. Since the material of the main body 120 is highly heat-conductive, the main body 120 may quickly take away heat generated by the electronic element 20 to cool down the electronic element 20. In addition, as shown in FIG. 5, in the present embodiment, since the heat dissipation fins 124 are disposed on the main body 120, a heat dissipation area is considerably increased, so that heat may be quickly taken away from the main body 120. In this way, the pickup and contact device 100 may effectively cool down the electronic element 20 being tested.

Further, in the present embodiment, with reference to FIG. 2 and FIG. 5 together, since the connection member 110 covers one side of the base 122 close to the heat dissipation fins 124, and this side is close to a central position, a clearance zone 125 is disposed on an upper side of the base 122 so that the connection member 110 may be conveniently bonded to the main body 120. The clearance zone 125 is not provided with the heat dissipation fins 154. As shown in FIG. 5, the heat dissipation fins 124 stand on the base 122 and surround the clearance zone 125 located in a center. In this embodiment, the heat dissipation fins 124 are evenly distributed on a portion outside the clearance zone 125. Moreover, the heat dissipation fins 124 located outside the clearance zone 125 have identical sizes and are arranged with the same arrangement density.

Certainly, in other embodiments, the heat dissipation fins 124 may have various sizes and may be arranged with different arrangement densities, or the clearance zone 125 may not have to be provided so that the heat dissipation fins 124 are disposed all over the base 122. In other embodiments, the heat dissipation fins 124 closer to a heat source (the electronic element 20) may be more densely distributed.

As shown in FIG. 5, the main body 120 further includes a plurality of fixing convex columns 127 located among the heat dissipation fins 124. The fixing convex columns 127 are flushed with the heat dissipation fins 124. In the present embodiment, the fixing convex columns 127 are as high as the heat dissipation fins 124 and thus may be conveniently manufactured. For instance, a manufacturer may cut a rectangular metal block into grooves so as to divide the rectangular metal block into the heat dissipation fins 124 and the fixing convex columns 127.

The fixing convex columns 127 have a plurality of first fixing holes 128, and the connection member 110 includes a plurality of second fixing holes 113 corresponding to the first fixing holes 128. The pickup and contact device 100 further includes a plurality of locking members 130 (FIG. 3). Each of the locking members 130 is adapted to penetrate through one of the corresponding first fixing hole 128 and the second fixing hole 113 and to be locked to the other one of the corresponding first fixing hole 113 and the second fixing hole 128. Certainly, in other embodiments, the connection member 110 and the main body 120 may also be fixed through other manners such as engagement, riveting, and adhesion.

In addition, a heat dissipation pad (not shown) or heat dissipation paste (not shown) may also be provided between the connection member 110 and the main body 120, so that heat may be transmitted to the connection member 110. A material of the connection member 110 may include metal, graphite, or highly heat-conductive plastic, so heat may be quickly taken away. But the material of the connection member 110 is not limited thereto.

As shown in FIG. 6, when the electronic element 20 is tested in the electrical testing zone 30, heat emitted from the electronic element 20 is adapted be transmitted to the heat dissipation fins 124 through the contact portion 123 of the main body 120 and the base 122, so that the heat is dissipated. Besides, in the present embodiment, the pickup and contact device 100 further includes a fan 140 disposed next to the heat dissipation fins 124, so that airflow near the heat dissipation fins 124 is accelerated, and that a temperature is lowered rapidly.

In the present embodiment, a plurality of grooves may be dug up on the main body 120 of the pickup and contact device 100 to form the heat dissipation fins 124 to increase the heat dissipation area. Through actual testing, when the electronic element 20 is tested in the electrical testing zone 30, if the pickup and contact device 100 of this embodiment is used to suck the electronic element 20, a temperature of the electronic element 20 may be maintained at 40 degrees or lower (e.g., 35 degrees), so that a favorable testing condition is maintained. That is, as long as a portion of the main body of the pickup and contact device is dug up to form the heat dissipation fins 124, the temperature of the electronic element 20 may be effectively reduced. In this way, a low-temperature or high-pressure workstation is not required to be additionally purchased, machine costs are thereby saved and the expected heat dissipation effect is also achieved. Certainly, in other embodiments, the heat dissipation fins 124 may be added to the main body of the pickup and contact device, and the foregoing effect may also be achieved in this way.

In view of the foregoing, the pickup and contact device provided by the disclosure is provided with the heat dissipation fins. When the electronic element is tested in the electrical testing zone, heat emitted by the electronic element is adapted to be transmitted out through the heat dissipation fins on the main body, and the temperature of the electronic element is thereby lowered. In this way, even if the electronic element is tested in a normal-temperature and normal-pressure testing environment, the pickup and contact device exhibiting a favorable heat dissipation property may also be used to prevent the electronic element from malfunctioning caused by overheating in the testing process.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pickup and contact device, adapted to be connected to a moving device so as to move a picked-up electronic element to an electrical testing zone, wherein the moving device pressurizes the electronic element through the pickup and contact device so that a contact point of the electronic element stably contacts a contact pad of the electrical testing zone, and the pickup and contact device further comprises:
a main body, comprising a base and a contact portion and a plurality of heat dissipation fins disposed at the opposite side of the contact portion of the base, wherein the contact portion is adapted to pick up the electronic element and to move the electronic element to the electrical testing zone along with the moving device, and heat emitted from the electronic element is adapted to be transmitted out through the heat dissipation fins of the main body when the electronic element is tested in the electrical testing zone.

2. The pickup and contact device according to claim 1, wherein the main body further comprises a plurality of fixing convex columns located among the heat dissipation fins, the fixing convex columns have a plurality of first fixing holes, and the fixing convex columns are flushed with the heat dissipation fins.

3. The pickup and contact device according to claim 1, wherein the heat dissipation fins stand on the base and surround a clearance zone located in a center, and the heat dissipation fins are evenly distributed on a portion outside the clearance zone.

4. The pickup and contact device according to claim 1, further comprising:
a pipeline, penetrating through the main body and extending to the contact portion, wherein the pipeline is adapted to apply a negative pressure inside to suck the electronic element.

5. The pickup and contact device according to claim 1, further comprising:
a connection member, detachably disposed at one side of the main body near the heat dissipation fins, wherein the connection member is adapted to be connected to the moving device together with the main body.

6. The pickup and contact device according to claim 5, wherein the heat dissipation fins stand on the base and surround a clearance zone located in a center, and the connection member covers the clearance zone.

7. The pickup and contact device according to claim 5, wherein the main body comprises a plurality of first fixing holes, the connection member comprises a plurality of second fixing holes corresponding to the first fixing holes, the pickup and contact device further comprises a plurality of locking members, and each of the locking members is adapted to penetrate through one of the corresponding first fixing hole and the second fixing hole and to be locked to the other one of the corresponding first fixing hole and the second fixing hole.

8. The pickup and contact device according to claim 5, wherein the connection member comprises a clip adapted to clip to the moving device.

9. The pickup and contact device according to claim 1, further comprising a fan, dispose next to the heat dissipation fins.

10. The pickup and contact device according to claim 1, wherein a material of the main body comprises metal, graphite, or highly heat-conductive plastic.
